(19) United States
(12) Patent Application Publication
(10) Pub. No.: US 2025/0046565 A1
(43) Pub. Date: Feb. 6, 2025

(54) Charged Particle Beam Device

(71) Applicant: Hitachi High-Tech Corporation, Minato-ku, Tokyo (JP)

(72) Inventors: Tomonori NAKANO, Tokyo (JP); Yu YAMAZAWA, Tokyo (JP)

(21) Appl. No.: 18/719,916

(22) PCT Filed: Feb. 14, 2022
(86) PCT No.: PCT/JP2022/005697

§ 371 Date: Jun. 14, 2024

(51) Int. Cl. H01J 37/147; H01J 37/26; H01J 37/28

(52) U.S. Cl. CPC H01J 37/1474; H01J 37/265; H01J 37/28

(57) ABSTRACT

In a charged particle beam device provided with an aberration corrector, a decrease in resolution that may occur when a scanning region is widened is prevented. A charged particle source (ES) generates a charged particle beam (EB). An aberration corrector 20 is provided on a path through which the charged particle beam passes, and corrects an aberration using multi-stage multipole lenses HEX1 and HEX2. A first deflector (SC) is provided between the aberration corrector and a sample stage that allows a sample SPL to be loaded thereon, and controls an irradiation position IP of the charged particle beam on the sample. A second deflector DEF1 is provided between the charged particle source and the aberration corrector, and controls a trajectory within the aberration corrector along which the charged particle beam passes. The controller 17 controls a deflection amount of the second deflector based on the irradiation position IP controlled by the first deflector.

### TECHNICAL FIELD

The present invention relates to a charged particle beam device, for example, a charged particle beam device provided with an aberration corrector.

### BACKGROUND ART

Patent Literature 1 discloses a charged particle beam device including a higher-order aberration correction device capable of correcting a fifth-order spherical aberration and a third-order chromatic aberration. In the charged particle beam device, a transfer lens is disposed such that a main surface position thereof coincides with an image point of the aberration correction device. A lens intensity of the transfer lens is set such that an aberration generation point of the aberration correction device is projected to a front focal point of an objective lens.

Patent Literature 2 discloses a charged particle beam device capable of simultaneously cancelling a plurality of aberrations caused by a distribution of energy and an aperture angle of a charged particle beam. The charged particle beam device includes an aberration generating lens that generates an aberration when a charged particle beam passes off-axis, and a correction lens that focuses a trajectory on a main surface of the objective lens regardless of the energy of the charged particle beam. A main surface of the correction lens is disposed at a crossover position where a plurality of charged particle beams having different aperture angles focus after passing through the aberration generating lens.

Patent Literature 3 discloses a charged particle beam device capable of reducing the number of axis adjustment steps and an adjustment time even when a multi-stage multipole aberration corrector is provided. The charged particle beam device includes a multi-stage multipole aberration corrector, a deflector disposed at a front stage of the aberration corrector, a power supply including a quadrupole wobbler circuit that independently makes a slight movement in a quadrupole intensity at each stage of the multipole, an axial shift calculation unit that calculates an amount of shift of an image due to the slight movement in the quadrupole intensity, and a deflection amount calculation unit that calculates a deflection amount to be fed back to the multipole and the deflector according to the shift amount. The deflection amount calculated by the deflection amount calculation unit is obtained by performing multi-stage deflection in the aberration corrector in conjunction.

### CITATION LIST

### Patent Literature

Patent Literature 1: JP2007-128656A
Patent Literature 2: JP2015-95297A
Patent Literature 3: JP2016-143558A

### SUMMARY OF INVENTION

### Technical Problem

For example, as disclosed in Patent Literatures 1 to 3, a charged particle beam device provided with an aberration corrector is known. The aberration corrector is implemented by a multi-stage multipole lens including magnetic poles and electrodes, and corrects aberrations that may occur in the objective lens or the like. In the charged particle beam device provided with the aberration corrector, the aperture angle is made larger than that of a device not provided with the aberration corrector, and consequently, a diffraction aberration is reduced, and thus high resolution observation can be performed. However, when the aperture angle increases, when performing large-field observation or observation by image shift, that is, when a scanning region of the charged particle beam is widened, there is a risk that blurring at positions away from a central axis becomes large and resolution decreases.

The invention has been made in view of the above, and an object of the invention is to prevent a decrease in resolution that may occur when a scanning region is expanded in a charged particle beam device provided with an aberration corrector.

The above and other objects and novel features of the invention will become apparent from the description of this specification and the accompanying drawings.

### Solution to Problem

An outline of a representative embodiment of the invention disclosed in the present application will be briefly described as follows.

A charged particle beam device according to a representative embodiment of the invention includes a charged particle source, a sample stage, an aberration corrector, a first deflector, a second deflector, and a controller. The charged particle source generates a charged particle beam. The sample stage is provided with a sample. The aberration corrector is provided on a path through which the charged particle beam passes, and corrects an aberration using a multi-stage multipole lens. The first deflector is provided between the aberration corrector and the sample stage, and controls an irradiation position of the charged particle beam on the sample. The second deflector is provided between the charged particle source and the aberration corrector, and controls a trajectory within the aberration corrector along which the charged particle beam passes. The controller controls a deflection amount of the second deflector based on the irradiation position controlled by the first deflector.

### Advantageous Effects of Invention

When an outline of a representative embodiment of the invention disclosed in the present application is briefly described, it is possible to prevent a decrease in resolution that may occur when a scanning region is widened in a charged particle beam device provided with an aberration corrector.

### BRIEF DESCRIPTION OF DRAWINGS

FIG. 1 is a schematic diagram showing a configuration example of a main portion of a charged particle beam device according to Embodiment 1.

FIG. 2 is a schematic diagram showing an example of an observation method using the charged particle beam device shown in FIG. 1.

FIG. 3 is a schematic diagram showing a configuration example and an operation example of a part of the charged particle beam device shown in FIG. 1.

FIG. 4A is a schematic diagram showing a configuration example of a control table in FIG. 3.

FIG. 4B is a schematic diagram showing an example of a relationship between a scanning position and a deflection amount based on the control table of FIG. 4A.

FIG. 5A is a diagram showing an example of a result obtained by verifying a relationship between scanning positions and blur amounts for different device configurations in the charged particle beam device shown in FIG. 3.

FIG. 5B is a diagram showing an example of a result obtained by verifying the relationship between the scanning positions and the blur amounts for different device configurations in the charged particle beam device shown in FIG. 3.

FIG. 6A is a diagram showing an example of a result obtained by comparing maximum blur amounts for different device configurations in the charged particle beam device shown in FIG. 3.

FIG. 6B is a diagram showing an example of a result obtained by comparing the maximum blur amounts for different device configurations in the charged particle beam device shown in FIG. 3.

FIG. 7 is a schematic diagram showing an example of display contents displayed on a display device in the charged particle beam device shown in FIGS. 1 and 3.

FIG. 8 is a schematic diagram showing a configuration example and an operation example of a part in FIG. 1 of a charged particle beam device according to Embodiment 2.

FIG. 9 is a diagram showing an example of a result obtained by comparing maximum blur amounts for different device configurations in the charged particle beam device shown in FIG. 8.

FIG. 10 is a schematic diagram showing a configuration example and an operation example of a part in FIG. 1 of a charged particle beam device according to Embodiment 3.

FIG. 11A is a schematic diagram showing a configuration example of a control table in FIG. 10.

FIG. 11B is a schematic diagram showing an example of a relationship between a scanning position and a deflection amount after an image shift based on the control table of FIG. 11A.

FIG. 12A is a diagram showing an example of a blur caused by scanning of an electron beam.

FIG. 12B is a diagram showing an example of scanning distortion caused by the scanning of the electron beam.

### DESCRIPTION OF EMBODIMENTS

Hereinafter, embodiments of the invention will be described in detail with reference to the drawings. In the drawings illustrating the embodiments, the same members are denoted by the same reference signs in principle, and repeated description thereof is omitted.

### Embodiment 1

### <Schematic Configuration of Charged Particle Beam Device>

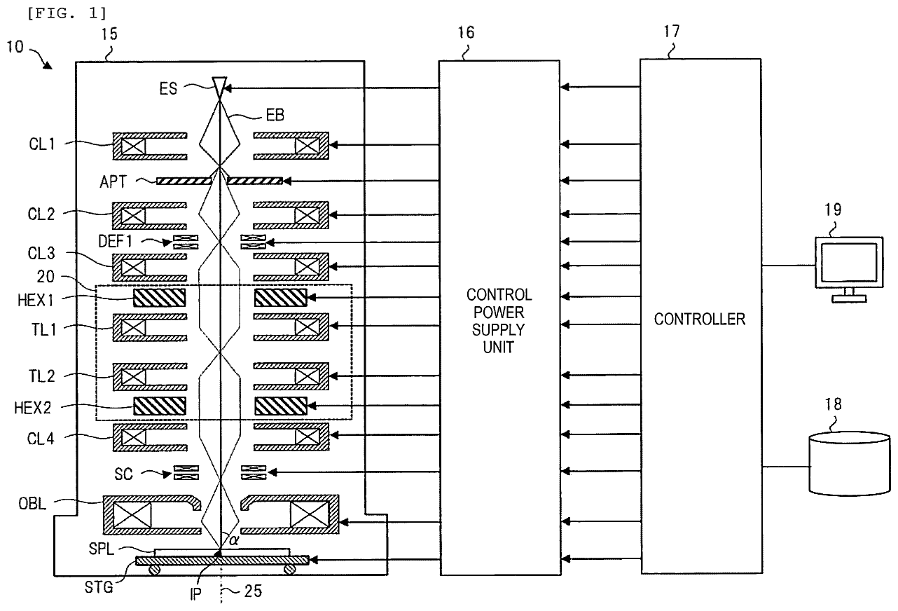

FIG. 1 is a schematic diagram showing a configuration example of a main portion of a charged particle beam device according to Embodiment 1. A charged particle beam device 10 shown in FIG. 1 is, for example, a scanning electron microscope (SEM) or a scanning transmission electron microscopy (STEM). In the specification, an electron beam is used as a charged particle beam, and the charged particle beam is not limited to the electron beam and may be, for example, an ion beam.

The charged particle beam device 10 shown in FIG. 1 includes a vacuum container 15, a control power supply unit 16, a controller 17, a storage device 18, and a display device 19. In the vacuum container 15, an electron source ES serving as a charged particle source, condenser lenses CL1 to CL4, an aperture APT, a deflector (second deflector) DEF1, an aberration corrector 20, a scanning coil (first deflector) SC, an objective lens OBL, and a sample stage STG are provided.

The electron source ES generates an electron beam EB. The condenser lens CL1 focuses the electron beam EB generated by the electron source ES. The aperture APT controls an aperture angle α of the electron beam EB by removing an unnecessary region of the electron beam EB. The condenser lens CL2 focuses the electron beam EB passing through the aperture APT. The condenser lens CL3 converts the electron beam EB focused by the condenser lens CL2 into a parallel electron beam EB and outputs the electron beams EB to the aberration corrector 20.

The deflector (second deflector) DEF1 is provided between the electron source ES and the aberration corrector 20, specifically, between the condenser lens CL2 and the condenser lens CL3. The deflector DEF1 deflects the electron beam EB passing through the condenser lens CL2 to control a trajectory in the aberration corrector 20 along which the electron beam EB passes, which will be described in detail later.

The aberration corrector 20 corrects an aberration caused by the objective lens OBL and the like using a multi-stage multipole lens provided on a path through which the electron beam EB passes. In this example, the aberration corrector 20 includes hexapole two-stage multipole lenses HEX1 and HEX2 and transfer lenses TL1 and TL2. The parallel electron beam EB passing through the condenser lens CL3 passes through the multipole lens HEX1. The electron beam EB passing through the multipole lens HEX1 is transferred to the multipole lens HEX2 by the two transfer lenses TL1 and TL2.

Each of the two-stage multipole lenses HEX1 and HEX2 has, for example, a 12-pole structure and excites a hexapole field. The two-stage multipole lenses HEX1 and HEX2 generate a rotationally symmetrical negative spherical aberration with an intensity corresponding to a distance from a central axis 25, thereby cancelling out a positive spherical aberration generated in the objective lens OBL and the like. The central axis 25 is a trajectory along which the electron beam EB travels straight, and is also an optical axis of the objective lens OBL. The second-stage multipole lens HEX2 excites a hexapole field that cancels out a three-fold astigmatism generated in the first-stage multipole lens HEX1.

The aberration corrector 20 may include, for example, a deflector (not shown) at a position between the transfer lens TL1 and the transfer lens TL2 or between the multipole lens HEX2 and the condenser lens CL4. In this case, optical axis adjustment based on the central axis 25 can be performed by the deflector or the deflector DEF1 shown in FIG. 1. In addition, the aberration corrector 20 is not limited to the configuration including such hexapole two-stage multipole lenses HEX1 and HEX2, and may include, for example, quadrupole to octupole four-stage multipole lenses that correct a spherical aberration and a chromatic aberration.

The condenser lens CL4 focuses the electron beam EB passing through the multipole lens HEX2 in the aberration corrector 20. The sample stage STG allows a sample SPL to be loaded thereon. The objective lens OBL focuses the electron beam EB passing through the condenser lens CL4 at an irradiation position IP on the sample SPL. At this time, a focusing half angle of the electron beam EB focused on the sample SPL is called an aperture angle α.

The scanning coil (first deflector) SC is provided between the aberration corrector 20 and the sample stage STG, specifically, between the condenser lens CL4 and the objective lens OBL, and controls the irradiation position IP of the electron beam EB on the sample SPL. Specifically, the scanning coil SC performs scanning of the electron beam EB, in other words, the irradiation position IP of the electron beam EB on the sample SPL. Alternatively, the scanning coil SC, when moving the scanning region of the electron beam EB on the sample SPL, shifts the irradiation position IP serving as an origin of a scanning region. Such an operation is called an image shift.

The scanning coil SC can perform scanning in the scanning region after moving the scanning region by the image shift. In this case, for example, the scanning coil SC scans the scanning region after the image shift by superimposing a variable component representing a deflection amount associated with the scanning in the scanning region on an offset component representing a deflection amount associated with the image shift. Here, although an example is shown in which the image shift and the scanning are performed using a common scanning coil SC, it is also possible to perform the image shift and the scanning using separate coils. In this case, in addition to the scanning coil that performs the scanning, an image shift coil that performs the image shift is additionally provided.

The control power supply unit 16 includes a plurality of power supplies, and operates the electron source ES, the condenser lenses CL1 to CL4, the aperture APT, the aberration corrector 20, the scanning coil SC, the objective lens OBL, and the sample stage STG using the plurality of power supplies. The sample stage STG is movable on a plane. The scanning region on the sample SPL is determined by appropriately combining the movement of the sample stage STG and the image shift. A negative voltage called retarding voltage is applied to the sample stage STG by the control power supply unit 16.

The controller 17 is implemented by, for example, a control computer including a processor and a memory. The controller 17 controls each power supply in the control power supply unit 16 to control, for example, an acceleration voltage of the electron beam EB from the electron source ES, a focal length of each lens, an aperture value of the aperture APT, a correction coefficient by the aberration corrector 20, and the deflection amount of each deflector. The storage device 18 is, for example, a nonvolatile memory such as a hard disk drive (HDD) or a solid-state drive (SSD), and stores various kinds of data and various programs used in the controller 17. The display device 19 serves as an interface with a user by displaying various kinds of information.

Although not shown in FIG. 1 for simplification of description, a detector or the like is further provided in the vacuum container 15. The detector detects an amount of secondary electrons or reflected electrons emitted from the sample SPL in response to irradiation of the electron beam EB, in other words, a primary electron beam. The amount of the secondary electrons and the reflected electrons changes according to a surface shape of the sample SPL and the like. A detection signal from the detector is output to the controller 17 through various signal processing circuits. The controller 17 creates a detection image representing the surface shape and the like of the sample SPL based on the detection signal and displays the detection image on the display device 19.

### <Problem When Using Aberration Corrector>

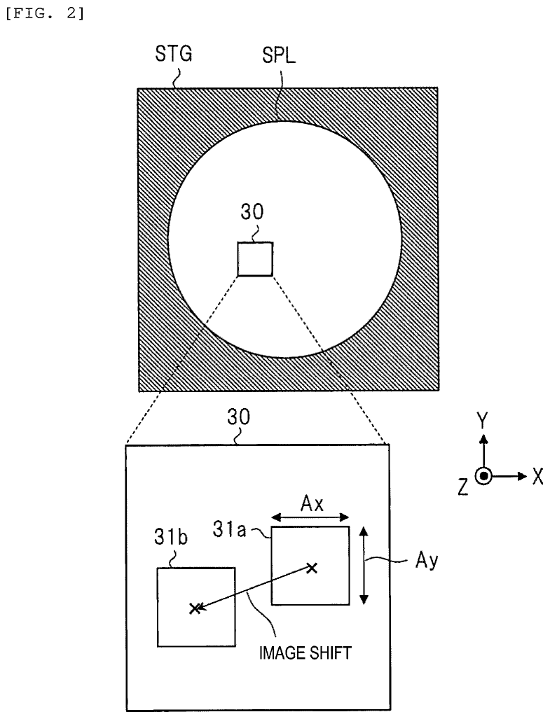

FIG. 2 is a schematic diagram showing an example of an observation method using the charged particle beam device shown in FIG. 1. FIG. 2 shows a state in which the sample SPL such as a semiconductor device is mounted on the sample stage STG. Examples of the observation method using the charged particle beam device 10 mainly include large-field observation, observation by image shift, and high resolution observation. The large-field observation is a method for observing a relatively wide large-field observation region 30 at a low magnification as shown in FIG. 2 by greatly changing the deflection amount of the scanning coil SC shown in FIG. 1, that is, by widening the scanning region.

The observation by the image shift is a method for observing relatively narrow observation regions 31a and 31b at a high magnification as shown in FIG. 2 by changing the deflection amount of the scanning coil SC shown in FIG. 1 to be small, that is, by narrowing the scanning region. At this time, for example, by adding an offset to the deflection amount of the scanning coil SC, the observation is performed after moving from the observation region 31a to the observation region 31b. A movement amount of the image shift is, for example, several μm to several tens of μm. A size Ax in an X-axis direction and a size Ay in a Y-axis direction of the observation regions 31a and 31b, in other words, the scanning region, are, for example, 1 μm or less. The magnification is determined by a ratio of the size of the observation region to the size of the detection image.

The high resolution observation is a method for observing a narrow observation region around the central axis 25 in FIG. 1 at a high magnification by changing the deflection amount of the scanning coil SC to be small without performing the image shift. When the aberration corrector 20 is used, it is possible to reduce the diffraction aberration by increasing the aperture angle α of the electron beam EB, and to mainly correct the spherical aberration which is a third-order aberration according to the aperture angle α. Accordingly, in a narrow observation region around the central axis 25, it is possible to perform the high resolution observation as compared with a charged particle beam device not provided with the aberration corrector 20.

Here, in the case of performing the large-field observation or the image shift, that is, in the case in which the scanning region of the electron beam EB is widened, due to an aberration caused by a combination of a large aperture angle α and an inclination angle of the electron beam EB, the blur at the irradiation position IP away from the central axis 25 is large, and resolution may decrease. In this case, the resolution may be lower than that of a charged particle beam device using a small aperture angle α, that is, a charged particle beam device not provided with the aberration corrector 20.

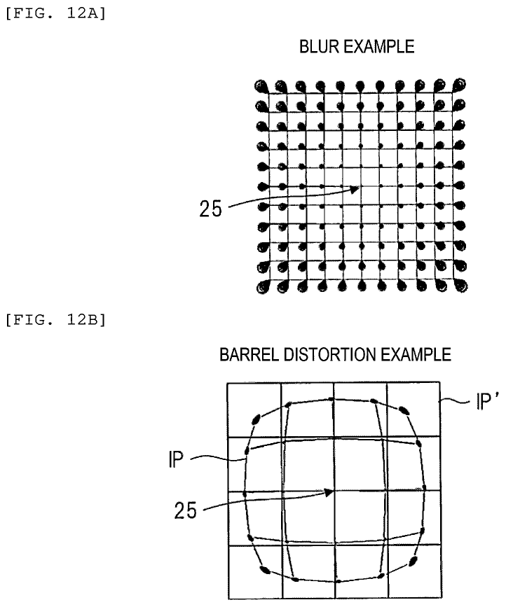

FIG. 12A is a diagram showing an example of a blur caused by scanning of the electron beam. FIG. 12A shows a state of the blur of the electron beam EB at each irradiation position IP when the scanning is performed in a 2 μm square scanning region. As shown in FIG. 12A, the blur becomes larger in a peripheral region away from the central axis 25. FIG. 12B is a diagram showing an example of scanning distortion caused by the scanning of the electron beam. FIG. 12B shows a state in which an actual irradiation position IP is shifted from an ideal irradiation position IP′ when the scanning region is wide. When such blur or scanning distortion occurs, the resolution may decrease.

Therefore, even when performing the large-field observation or the observation by the image shift, it is desired to prevent the blur or the scanning distortion in the peripheral region as shown in FIGS. 12A and 12B and to prevent the decrease in the resolution. Even when the charged particle beam device 10 provided with the aberration corrector 20 is used for the large-field observation or the observation by the image shift, it is desired to achieve resolution equal to or higher than that of a charged particle beam device not provided with the aberration corrector 20.

### <Operation of Charged Particle Beam Device>

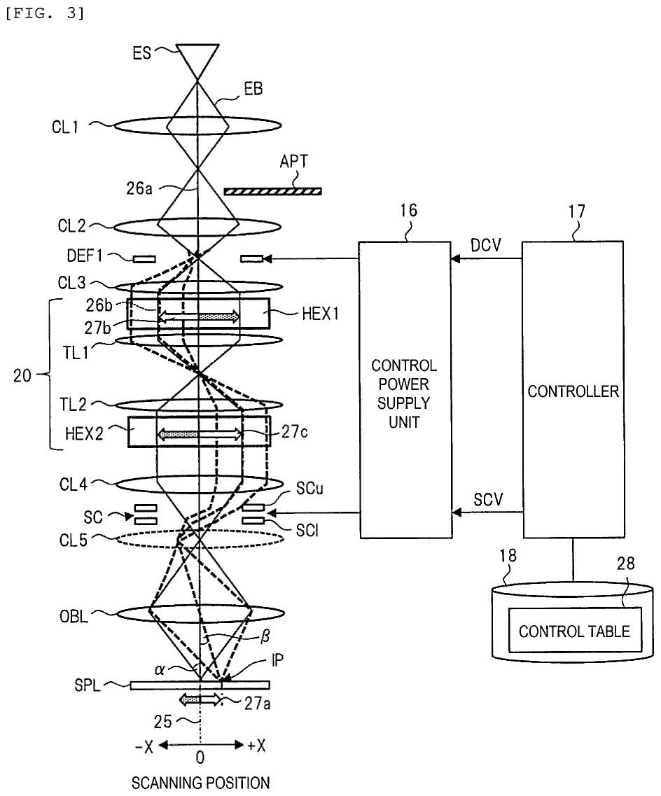

FIG. 3 is a schematic diagram showing a configuration example and an operation example of a part of the charged particle beam device shown in FIG. 1. FIG. 3 shows the electron source ES, the condenser lenses CL1 to CL4, the aperture APT, the deflector DEF1, the aberration corrector 20, the scanning coil SC, the objective lens OBL, the sample SPL, the control power supply unit 16, the controller 17, and the storage device 18 shown in FIG. 1. Further, in FIG. 3, a condenser lens (correction lens) CL5 is added.

The condenser lens CL5 is provided between the scanning coil SC and the objective lens OBL, and has a function of correcting a high-order aberration. The focal length of the condenser lens CL4 and the arrangement of the condenser lens CL5 are adjusted such that a crossover position of the condenser lens CL4 coincides with the main surface of the condenser lens CL5. The condenser lens CL5 is controlled such that a deflection fulcrum of the scanning coil SC is at the position of the objective lens OBL. The scanning coil SC performs two-stage deflection using a two-stage configuration including an upper coil SCu and a lower coil SCl.

In such a configuration, the controller 17 controls the deflection amount of the deflector (second deflector) DEF1 based on the irradiation position IP on the sample SPL controlled by the scanning coil (first deflector) SC. Specifically, the deflector DEF1 has a one-stage configuration. The controller 17 controls the deflection amount of the deflector DEF1 so that the trajectory along which the electron beam EB passes through the multipole lenses HEX1 and HEX2 of the aberration corrector 20 is translated from the central axis 25 according to the irradiation position IP controlled by the scanning coil SC. That is, the trajectory of the electron beam EB is changed from a trajectory 26a passing through the central axis 25 to a trajectory 26b away from the central axis 25.

More specifically, as indicated by arrows 27a and 27b in FIG. 3, the controller 17 controls the deflection amount of the deflector DEF1, with the central axis as 0, such that the trajectory 26b passing through the multipole lens HEX1 via the condenser lens CL3 is translated from 0 in a −X-axis direction as the irradiation position IP moves from 0 in a +X-axis direction. That is, the controller 17 controls the deflection amount of the deflector DEF1 such that the trajectory 26b is translated to a position away from the central axis 25. Accordingly, as indicated by an arrow 27c, the trajectory 26b passing through the multipole lens HEX2 is controlled to be translated from 0 in the +X-axis direction, that is, to be translated to a position away from the central axis 25.

Similarly, the controller 17 controls the deflection amount of the deflector DEF1 such that the trajectory 26b passing through the multipole lens HEX1 via the condenser lens CL3 is translated from 0 to the +X-axis direction as the irradiation position IP moves from 0 to the −X-axis direction. Accordingly, the trajectory 26b passing through the multipole lens HEX2 is controlled to be translated from 0 in the −X-axis direction. As described above, the deflection amount of the deflector DEF1 is controlled such that the trajectory 26b within the multipole lenses HEX1 and HEX2 is translated to a position away from the central axis 25 as the irradiation position IP is away from the central axis 25.

The aberration corrector 20 functions to generate an aberration in an opposite direction to an aberration generated by the objective lens OBL or the like, and cancel out the aberration generated by the objective lens OBL or the like. The same applies when scanning is performed on the electron beam EB, when the trajectory 26b is controlled to move away from the central axis 25 in conjunction with an inclination angle β of the electron beam EB with respect to the sample SPL, the aberration corrector 20 generates an aberration in the opposite direction to the aberration generated in the objective lens OBL or the like, for example, an aberration in the opposite direction having a similar tendency. As a result, the aberration caused by the objective lens OBL or the like according to the inclination angle β can be cancelled out by passing through the off-axis trajectory 26b of the aberration corrector 20.

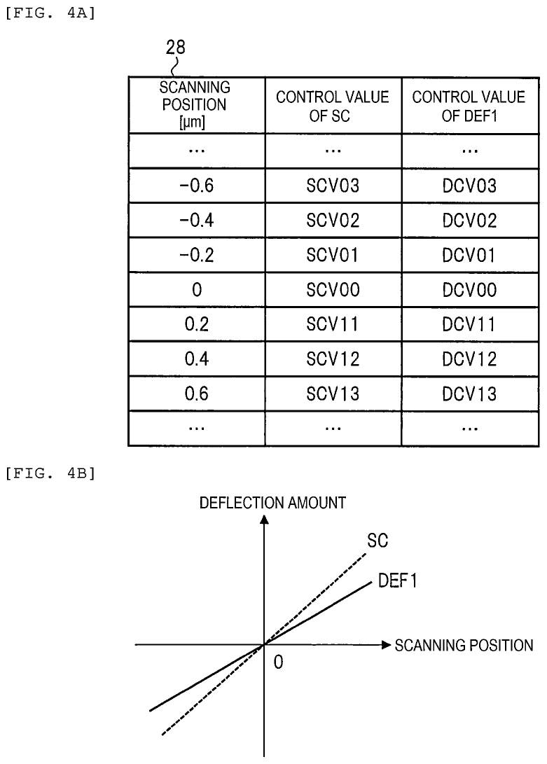

In order to perform such control, the storage device 18 stores a control table (first control table) 28. FIG. 4A is a schematic diagram showing a configuration example of the control table in FIG. 3. The control table 28 indicates a relationship among a scanning position obtained by the scanning coil SC, that is, the irradiation position IP, a control value SCV of the scanning coil SC, and thus the deflection amount, and a control value DCV of the deflector DEF1, and thus the deflection amount. The control table 28 is created in advance based on simulation or actual measurement and stored in the storage device 18.

The controller 17 controls the scanning position controlled by the scanning coil (first deflector) SC using the control value SCV based on the control table 28, and controls the deflection amount of the deflector DEF1 (second deflector) using the control value DCV. In the example shown in FIG. 4A, the control values SCV and DCV are determined for each scanning position in units of 0.2 μm. The control values SCV and DCV within 0.2 μm are approximately calculated by interpolation. A size of the unit of the scanning position may be determined, for example, according to the required resolution.

The control power supply unit 16 shown in FIG. 3 controls a power supply of the scanning coil SC, for example, a current value according to the control value SCV from the controller 17, thereby controlling the deflection amount of the scanning coil SC according to the control value SCV. Similarly, the control power supply unit 16 controls a power supply of the deflector DEF1, for example, a current value according to the control value DCV from the controller 17, thereby controlling the deflection amount of the deflector DEF1 according to the control value DCV.

FIG. 4B is a schematic diagram showing an example of a relationship between the scanning position and the deflection amount based on the control table of FIG. 4A. As shown in FIG. 4B, as the scanning position moves away from the central axis 25, that is, from 0, the deflection amount of the scanning coil SC increases, and the deflection amount of the deflector DEF1 also increases. In FIG. 4B, characteristics of a linear function are shown for simplification, but strictly speaking, the characteristics may be those of a trigonometric function or the like. In FIGS. 3 and 4A, although the scanning in one dimension, that is, in the X-axis direction, is taken as an example, specifically, the scanning in two dimensions, that is, in the X-axis direction and the Y-axis direction, is possible, and a control table corresponding to two dimensions is provided.

### <Simulation Result>

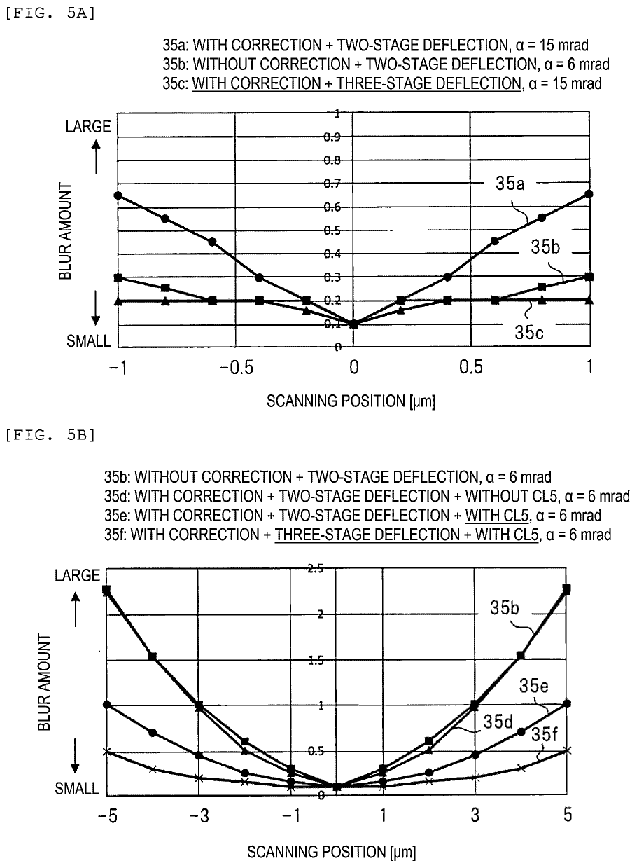

FIGS. 5A and 5B are diagrams showing an example of a result obtained by verifying a relationship between the scanning positions and blur amounts for different device configurations in the charged particle beam device shown in FIG. 3. The blur amounts shown in FIGS. 5A and 5B include a blur amount caused by the spherical aberration and a blur amount caused by the chromatic aberration. However, here, since the comparison is performed excluding an effect that the larger the aperture angle α is, the smaller the diffraction aberration is, a blur amount associated with the diffraction aberration and a blur amount associated with a light source size× an optical magnification are excluded from the blur amounts shown in FIGS. 5A and 5B.

Characteristics 35a, 35b, and 35c shown in FIG. 5A are those in the case in which the condenser lens CL5 for high-order aberration correction shown in FIG. 3 is not provided. The characteristic 35a is obtained when the aberration corrector 20 performs correction, when the two-stage deflection is used instead of the three-stage deflection as shown in FIG. 3, that is, the deflector DEF1 is not provided, and when the aperture angle α is set to 15 m[rad]. When the two-stage deflection is used, the trajectory of the electron beam EB within the aberration corrector 20 becomes the on-axis trajectory 26a passing through the central axis 25 regardless of the irradiation position IP. The characteristic 35a represents a characteristic of a general charged particle beam device provided with the aberration corrector 20.

The characteristic 35b is obtained when the aberration corrector 20 does not perform the correction, that is, when the aberration corrector 20 is not provided or is not caused to function, and when the two-stage deflection is used and the aperture angle α is set to 6 m[rad]. The characteristic 35b represents a characteristic of a general charged particle beam device not provided with the aberration corrector 20.

As shown in FIG. 5A, in the case with the correction shown in the characteristic 35a, since the aperture angle α is larger as compared with the case without the correction shown in the characteristic 35b, when the scanning region is widened, that is, when the inclination angle β is increased, the blur amount is larger than that in the characteristic 35b. In this example, when the scanning position exceeds about 200 [nm], the blur amount in the case with the correction is larger than that in the case without the correction.

A characteristic 35d shown in FIG. 5B is a characteristic obtained when the aberration corrector 20 performs the correction and when the two-stage deflection is used similarly to the characteristic 35a shown in FIG. 5A, and is a characteristic obtained when the aperture angle α is set to 6 m[rad] instead of 15 m[rad] unlike the characteristic 35a. As can be seen from the comparison between the characteristic 35d and the characteristic 35b in FIG. 5B, when the aperture angle α is the same, there is no large difference in the blur amount between the case with the correction and the case without the correction.

Meanwhile, the characteristic 35c in FIG. 5A is different from the characteristic 35a in the case with the correction and the two-stage deflection, and as shown in FIG. 3, is obtained in the case with the correction and the three-stage deflection. As can be seen from the comparison between the characteristic 35a and the characteristic 35c shown in FIG. 5A, in the case with the correction, the blur amount at the scanning position away from the central axis 25 can be greatly improved by using the three-stage deflection instead of the two-stage deflection.

Further, as can be seen from the comparison between the characteristic 35b and the characteristic 35c in FIG. 5A, by using a combination of the correction and the three-stage deflection, even when the scanning region is wide, it is possible to achieve a blur amount that is comparable to or smaller than that in the case without the correction, that is, the case in which the aperture angle α is small. More specifically, in the case with the correction, as compared with the case without the correction, it is possible to reduce the diffraction aberration by increasing the aperture angle α, and thus the blur amount becomes smaller.

FIG. 5B shows verification results when the aperture angles α are equal, here, are all 6 m[rad], and shows an effect obtained by the three-stage deflection and an effect obtained by the condenser lens (correction lens) CL5 for the high-order aberration correction. In FIG. 5B, the characteristic 35d is obtained in the case with the correction and the two-stage deflection, and further, in the case of not providing the condenser lens CL5. Meanwhile, the characteristic 35e is the same as the characteristic 35d in the case with the correction and the two-stage deflection, but is different from the characteristic 35d in the case of providing the condenser lens CL5. As can be seen from the comparison between the characteristic 35d and the characteristic 35e, by providing the condenser lens CL5, it is possible to greatly improve the blur amount at the scanning position away from the central axis 25.

A characteristic 35f, like characteristic 35e, is for the case with the correction and the case of providing the condenser lens CL5, but unlike characteristic 35e, it is for the case in which the three-stage deflection is used instead of the two-stage deflection. As can be seen from the comparison between the characteristic 35e and the characteristic 35f, by using the three-stage deflection, it is possible to further improve the blur amount at the scanning position away from the central axis 25.

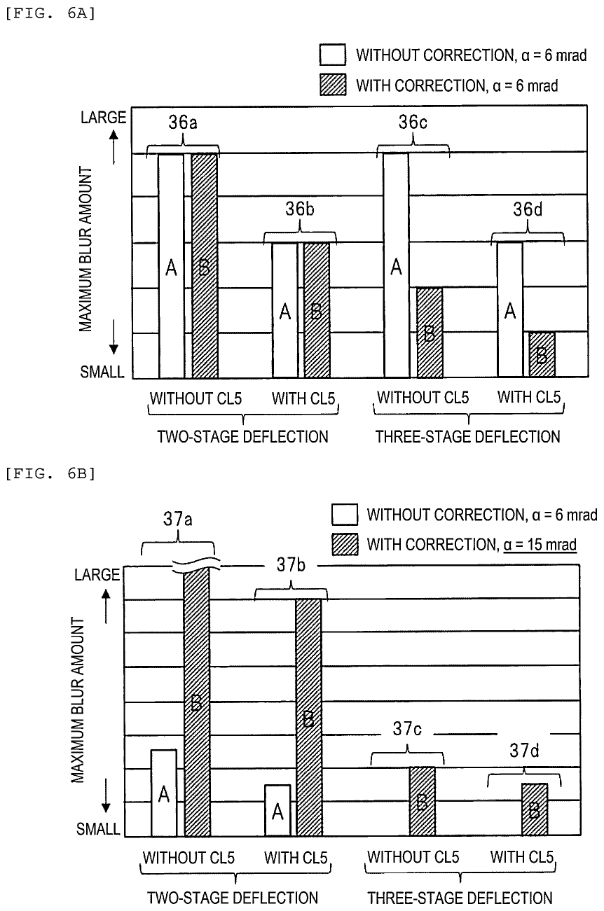

FIGS. 6A and 6B are diagrams showing an example of results obtained by comparing maximum blur amounts for different device configurations in the charged particle beam device shown in FIG. 3. Here, when the scanning is performed in a 2 μm square scanning region as shown in FIG. 12A, the results obtained by comparing the blur amounts at positions of four corners, which are maximum blur amounts, are shown.

In FIG. 6A, results 36a and 36b are obtained when the two-stage deflection is used, and results 36c and 36d are obtained when the three-stage deflection is used. In addition, in each of the results 36a to 36d, “A” is a case without the correction, and “B” is a case with the correction. In FIG. 6A, regardless of “A” and “B”, that is, regardless of presence or absence of the correction, the aperture angle α is equal, and both are 6 m[rad].

First, as can be seen from the comparison between “A” and “B” in the result 36a or the result 36b, when the aperture angle α is the same, the maximum blur amount is substantially the same regardless of the presence or absence of the correction. As can be seen from the comparison between the result 36a and the result 36b, by providing the condenser lens CL5, the maximum blur amount becomes smaller regardless of the presence or absence of the correction.

Meanwhile, as indicated by “B” in the result 36c, when the combination of the correction and the three-stage deflection is used, the maximum blur amount is smaller than that when the combination of no correction and the three-stage deflection indicated by “A” in the result 36c or the combination of no correction and the two-stage deflection indicated by “A” in the result 36a is used. When the condenser lens CL5 is further combined with the combination of the correction and the three-stage deflection indicated by “B” of the result 36c, the maximum blur amount becomes smaller as indicated by “B” of the result 36d.

In FIG. 6B, as in the case of FIG. 6A, results 37a and 37b are obtained when the two-stage deflection is used, and results 37c and 37d are obtained when the three-stage deflection is used. In addition, in each of the results 37a to 37d, “A” is a case without the correction, and “B” is a case with the correction. However, in FIG. 6B, the aperture angle α without the correction indicated by “A” is 6 m[rad] as in the case of FIG. 6A, but the aperture angle α with the correction is 15 m[rad] unlike the case of FIG. 6A.

In a general device configuration, the two-stage deflection is used, and for example, in the case without the correction, the result is obtained when “A” of the result 37a, that is, α=6 m[rad] is satisfied and the condenser lens CL5 is not provided, and in the case with the correction, the result is obtained when “B” of the result 37b, that is, α=15 m[rad] is satisfied and the condenser lens CL5 is provided. However, in the case with the correction, the maximum blur amount can be more than twice as large as that in the case without the correction.

In the case with the correction, by using the three-stage deflection, as indicated by “B” of the result 37c, the maximum blur amount can be reduced compared to “A” of the result 37a even without providing the condenser lens CL5. Further, when the condenser lens CL5 is combined, the maximum blur amount can be further reduced as indicated by “B” of the result 37d. The maximum blur amount indicated by “B” in the result 37d is about the same as that indicated by “A” in the result 37b when no correction and α=6 m[rad] are combined with the condenser lens CL5.

### <User Setting Function>

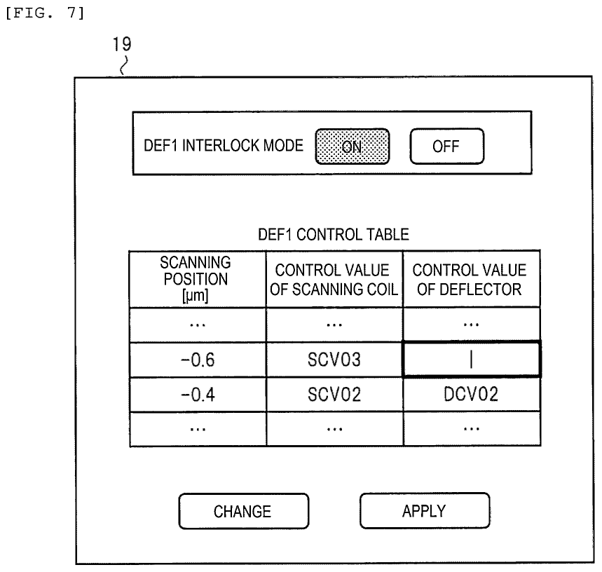

FIG. 7 is a schematic diagram showing an example of display contents displayed on the display device in the charged particle beam device shown in FIGS. 1 and 3. As shown in FIG. 7, the user can select, by setting, whether to enable/disable the operation of controlling the deflection amount of the deflector (second deflector) DEF1 via the display device 19. In this example, when ON of a “DEF1 interlock mode” is selected, interlocking control of the deflector DEF1 according to the scanning position as described in FIG. 3 is enabled, and when OFF is selected, the interlocking control is disabled. When the interlocking control is disabled, the trajectory of the electron beam EB within the aberration corrector 20 is maintained at the on-axis trajectory 26a shown in FIG. 3.

For example, when performing the high resolution observation as described in FIG. 2, that is, when observing a narrow observation region around the central axis 25 at a high magnification, it is possible to obtain sufficient resolution without using the interlocking control of the deflector DEF1. Meanwhile, when using the interlocking control in such high resolution observation, it is necessary to finely create the unit of the scanning position in the control table 28 shown in FIG. 4A to some extent, and the deflector DEF1 at the same level as the scanning coil SC, that is, the deflector DEF1 having high setting resolution of the deflection amount and a fast response speed may be required.

On the other hand, when performing the large-field observation or the observation by the image shift, it is often not required to have resolution as high as in the case of performing the high resolution observation. In this case, no particular problem arises even if the deflector DEF1 has somewhat low setting resolution and a somewhat slow response speed. For example, when using such a deflector DEF1, the user may disable the interlocking control when performing the high resolution observation and enable the interlocking control when performing the large-field observation or the observation by image shift, via the display device 19 as shown in FIG. 7.

As shown in FIG. 7, the user can refer to the control table 28 shown in FIG. 4A via the display device 19, and can change the contents of the control table 28. For example, in the charged particle beam device 10, variations may occur from device to device even if they are of the same model. In addition, a degree of variation may vary depending on an installation location of the device. In such a case, the contents of the control table 28 can be corrected via the display device 19 as shown in FIG. 7.

Here, although the control table 28 is stored in the storage device 18, a length measurement table may be further stored. For example, in a critical dimension-scanning electron microscope (CD-SEM), an error between a measurement value and a known pattern length is calculated by measuring a calibration sample or the like whose pattern length is known in advance, and a length measurement table including a correction value for correcting the error may be created. When the interlocking control of the deflector DEF1 is used, contents of the length measurement table may be changed, and thus it is desirable to separately create a length measurement table used in the interlocking control.

### Main Effects of Embodiment 1

As described above, in the method of Embodiment 1, in the charged particle beam device 10 provided with the aberration corrector 20, the one-stage deflector DEF1 is provided at the front stage of the aberration corrector 20, and the deflector DEF1 controls the deflection amount according to the scanning position of the electron beam EB, in other words, the irradiation position IP. Accordingly, it is possible to prevent a decrease in resolution that may occur when the aperture angle α of the electron beam EB is large and the scanning region is widened, that is, when the inclination angle β of the electron beam EB is large. In addition, even when the scanning region is widened, it is possible to achieve resolution equal to or higher than that of a charged particle beam device not provided with the aberration corrector 20, that is, a charged particle beam device using a small aperture angle α.

### Embodiment 2

### <Operation of Charged Particle Beam Device>

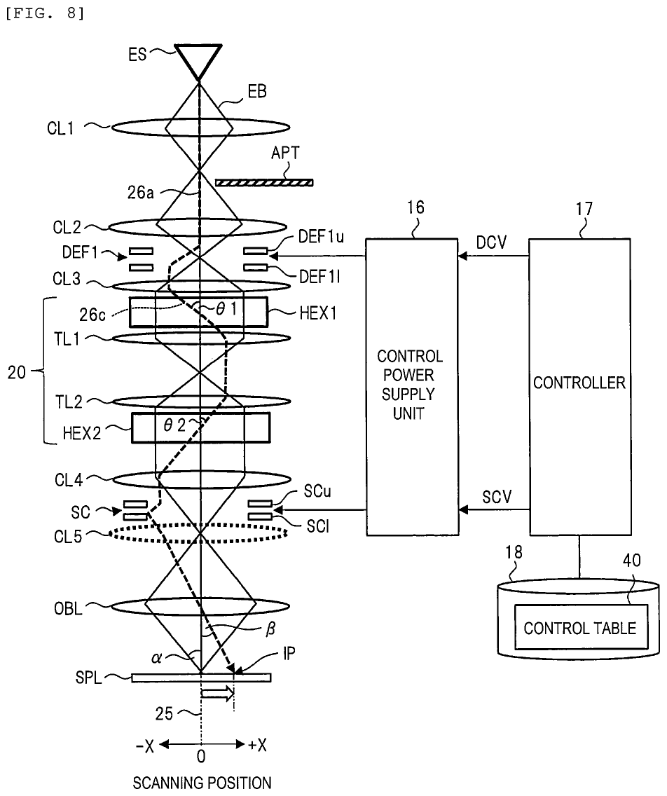

FIG. 8 is a schematic diagram showing a partial configuration example and an operation example in FIG. 1 in a charged particle beam device according to Embodiment 2. FIG. 8 shows a configuration example similar to the configuration example shown in FIG. 3. However, in FIG. 8, unlike the case of FIG. 3, the deflector DEF1 provided at the front stage of the aberration corrector 20 does not have a one-stage configuration but has a two-stage configuration including an upper deflector DEF1u and a lower deflector DEF11.

As in the case of FIG. 3, the controller 17 controls the deflection amount of the deflector (second deflector) DEF1 based on the irradiation position IP on the sample SPL controlled by the scanning coil (first deflector) SC. However, unlike the case of FIG. 3, the controller 17 controls the deflection amount of the deflector DEF1 such that angles θ1 and θ2 formed by a trajectory along which the electron beam EB passes through the multipole lenses HEX1 and HEX2 of the aberration corrector 20 and the central axis 25 change according to the irradiation position IP controlled by the scanning coil SC. That is, the trajectory of the electron beam EB is changed from the trajectory 26a passing through the central axis 25 to a trajectory 26c having an angle with respect to the central axis 25.

More specifically, the controller 17 controls the deflection amount of the deflector DEF1, with the central axis as 0, such that the angle θ1 of the trajectory 26c passing through the multipole lens HEX1 via the condenser lens CL3 with respect to the central axis 25 increases as the irradiation position IP moves from 0 in the +X-axis direction. Accordingly, the angle θ2 of the trajectory 26c passing through the multipole lens HEX2 with respect to the central axis 25 is also controlled to be large. Accordingly, an aberration caused by the inclination angle β of the electron beam EB with respect to the sample SPL can be cancelled out by passing through the off-axis trajectory 26c of the aberration corrector 20.

In FIG. 8, the storage device 18 stores the control table 40 similar to that in FIG. 4A. However, the control value of the deflector DEF1 includes a control value for the upper deflector DEF1u and a control value for the lower deflector DEF11. As in the case of FIG. 3, more specifically, a control table corresponding to two-dimensional scanning, that is, the scanning in the X-axis direction and the Y-axis direction is provided.

### <Simulation Result>

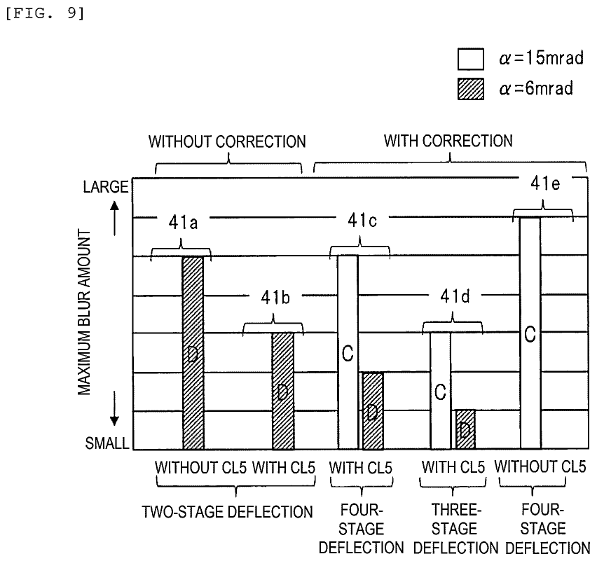

FIG. 9 is a diagram showing an example of a result obtained by comparing maximum blur amounts for different device configurations in the charged particle beam device shown in FIG. 8. Here, as in the case of FIGS. 6A and 6B, when the scanning is performed in a 2 μm square scanning region of as shown in FIG. 12A, the results obtained by comparing the blur amounts at positions of four corners, which are maximum blur amounts, are shown.

In FIG. 9, results 41a and 41b are obtained in the case without the correction, and both are for the case in which the two-stage deflection is used. Results 41c, 41d, and 41e are obtained in the case with the correction, and are for the cases in which a four-stage deflection, the three-stage deflection, and the four-stage deflection are used, respectively. In addition, in each of the results 41a to 41e, “C” indicates a case in which the aperture angle α is 15 m[rad], and “D” indicates a case in which the aperture angle α is 6 m[rad].

As can be seen from the comparison between “D” of the result 41b and “D” of the result 41c, when both have the same aperture angle α and the condenser lens (correction lens) CL5 is provided, by using the combination of the correction and the four-stage deflection as shown in FIG. 8, the maximum blur amount is smaller than the case without the correction. As can be seen from the comparison between the result 41c and the result 41d, when the four-stage deflection shown in FIG. 8 and the three-stage deflection shown in FIG. 3 are compared, the maximum blur amount is smaller in the three-stage deflection. “C” of the result 41e is different from “C” of the result 41c, and indicates the case in which the condenser lens CL5 is not provided. When the condenser lens CL5 is not provided, the maximum blur amount is larger than the case in which the condenser lens CL5 is provided.

### Main Effects of Embodiment 2

As described above, even when the deflector DEF1 having the four-stage deflection, that is, the two-stage deflection, is used instead of the deflector DEF1 having the three-stage deflection, that is, the one-stage deflection, as in the method of Embodiment 2, it is possible to obtain the effects same as the various effects described in Embodiment 1. That is, it is possible to prevent a decrease in resolution that may occur when the aperture angle α of the electron beam EB is large and the scanning region is widened, that is, when the inclination angle β of the electron beam EB is large.

### Embodiment 3

### <Operation of Charged Particle Beam Device>

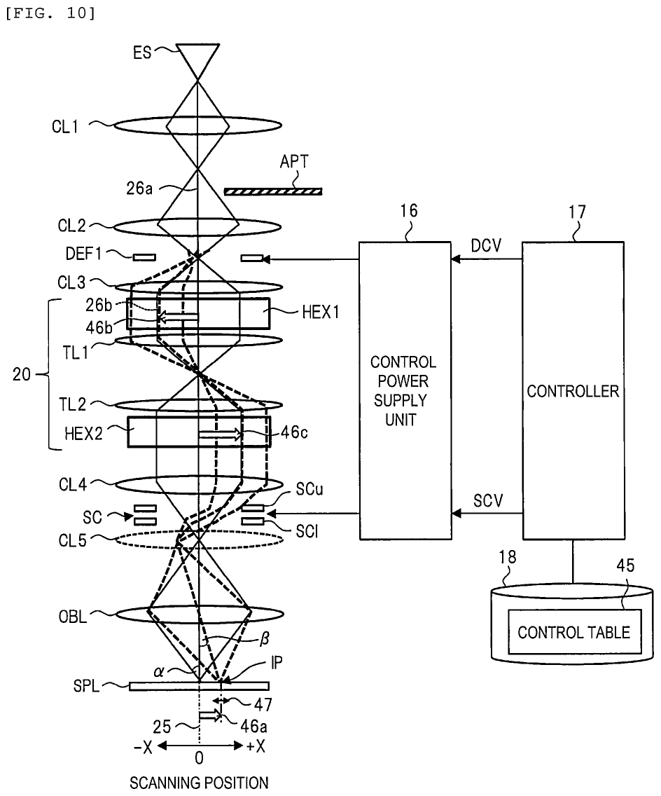

FIG. 10 is a schematic diagram showing a configuration example and an operation example of a part in FIG. 1 of a charged particle beam device according to Embodiment 3. FIG. 10 shows a configuration example similar to the configuration example shown in FIG. 3. However, in FIG. 10, unlike the case of FIG. 3, the scanning coil (first deflector) SC performs the image shift instead of the scanning. That is, the scanning coil SC, when moving the scanning region of the electron beam EB on the sample SPL, shifts the irradiation position IP serving as an origin of a scanning region. The controller 17 controls the deflection amount of the deflector (second deflector) DEF1 based on the shift amount of the scanning coil SC.

A detailed control method of the deflection amount of the deflector DEF1 is substantially the same as that of FIG. 3. That is, as indicated by arrows 46a and 46b in FIG. 10, when the irradiation position IP serving as the origin is shifted from 0 to a predetermined position in the +X-axis direction, the controller 17 controls the deflection amount of the deflector DEF1 such that the trajectory 26b passing through the multipole lens HEX1 via the condenser lens CL3 is translated from 0 to a predetermined position in the −X-axis direction. Accordingly, as indicated by an arrow 46c, the trajectory 26b passing through the multipole lens HEX2 is controlled to be translated from 0 to the predetermined position in the +X-axis direction.

In the state in which the image shift is performed as described above, the scanning coil SC further performs the scanning of the electron beam EB in a scanning region 47 after the image shift is performed. However, unlike the case of FIG. 3, the controller 17 maintains the deflection amount of the deflector DEF1 while the scanning coil SC performs the scanning in the scanning region 47. With such an operation, the storage device 18 shown in FIG. 10 stores a control table (second control table) 45 different from that shown in FIG. 3.

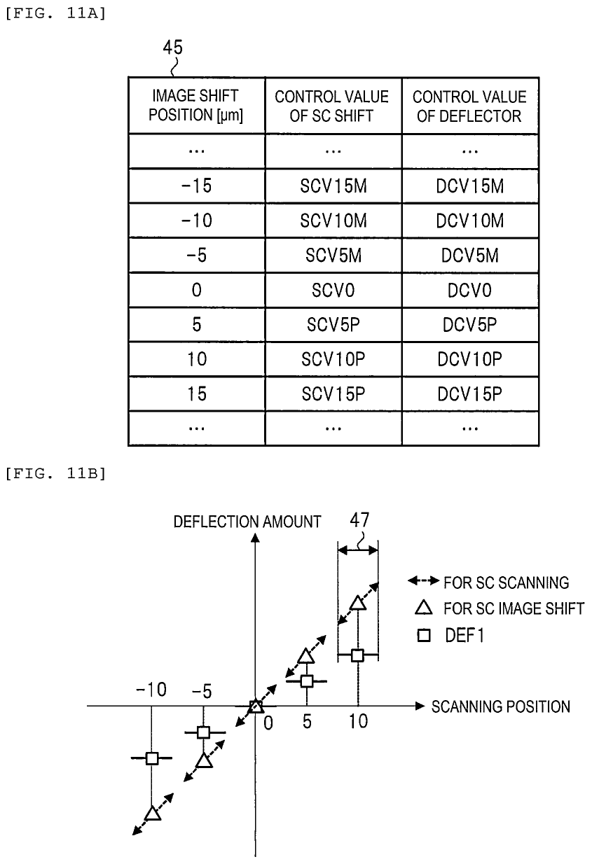

FIG. 11A is a schematic diagram showing a configuration example of the control table in FIG. 10. In the control table (second control table) 45 shown in FIG. 11A, unlike the control table (first control table) 28 shown in FIG. 4A, the unit of the scanning position is a value based on an image shift amount, and in this example, is a unit of 5 μm. The controller 17 controls, based on the control table 45, the image shift amount of the scanning coil SC using the control value SCV and controls the deflection amount of the deflector DEF1 using the control value DCV. Here, in the case of FIG. 4A, the control value DCV of the deflector DEF1 within the unit of scanning position is calculated by interpolation, but in the case of FIG. 11A, such interpolation is not necessary.

FIG. 11B is a schematic diagram showing an example of a relationship between the scanning position and the deflection amount after the image shift based on the control table of FIG. 11A. As shown in FIG. 11B, the deflection amount of the deflector DEF1 is controlled to correspond to the shift amount of the scanning coil SC on a one-to-one basis. Further, the deflection amount of the deflector DEF1 is maintained while the scanning coil SC performs the scanning of the electron beam EB in the scanning region 47 after the image shift is performed.

Strictly speaking, the characteristics shown in FIG. 11B are not linear functions but may be characteristics such as trigonometric functions, as described in FIG. 4B. As described in FIG. 4B, specifically, a control table corresponding to the two-dimensional image shift is provided. Further, although the three-stage deflection is used in FIG. 10, the four-stage deflection as shown in FIG. 8 may be used instead. Here, although the control table 45 is used for the observation by the image shift, the table may be used for large-scale observation. In this case, in FIG. 11B, the deflection amount of the scanning coil SC changes linearly, and the deflection amount of the deflector DEF1 changes stepwise.

### Main Effects of Embodiment 3

As described above, in the method of Embodiment 3, the deflection amount of the deflector DEF1 is controlled in conjunction with the image shift amount. Accordingly, it is also possible to obtain the effects same as the various effects described in Embodiment 1. That is, it is possible to prevent a decrease in resolution that may occur when the aperture angle α of the electron beam EB is large and the scanning region is widened, that is, when the inclination angle β of the electron beam EB is large.

When being in conjunction with the image shift amount, the resolution may decrease as compared with the case of being in conjunction with the scanning amount as described in Embodiment 1. However, the resolution required for the observation by the image shift or the large-field observation is sufficiently obtained. Further, as described with reference to FIG. 7, cost of the deflector DEF1 can be reduced or the like by sacrificing the resolution to some extent when performing the observation by the image shift or the large-field observation.

Although the invention made by the present inventor has been specifically described based on embodiments, the invention is not limited to the embodiments, and various modifications can be made without departing from the gist of the invention. For example, the above-described embodiments have been described in detail to facilitate understanding of the invention, and the invention is not necessarily limited to those including all the configurations described above. In addition, a part of a configuration according to a certain embodiment can be replaced with a configuration according to another embodiment, and a configuration according to another embodiment can be added to a configuration according to a certain embodiment. In addition, another configuration can be added to, deleted from, or replaced with a part of a configuration of each embodiment.

### REFERENCE SIGNS LIST

10: charged particle beam device
17: controller
18: storage device
20: aberration corrector
25: central axis
26a to 26c: trajectory of electron beam
28, 40, 45: control table
CL5: condenser lens (correction lens)
DEF1: deflector (second deflector)
EB: electron beam (charged particle beam)
ES: electron source (charged particle source)
HEX1, HEX2: multipole lens
IP: irradiation position
OBL: objective lens
SC: scanning coil (first deflector)
SPL: sample
STG: sample stage

1. A charged particle beam device comprising:
a charged particle source configured to generate a charged particle beam;
a sample stage configured to allow a sample to be loaded thereon;
an aberration corrector provided on a path through which the charged particle beam passes and configured to correct an aberration using a multi-stage multipole lens;
a first deflector provided between the aberration corrector and the sample stage and configured to control an irradiation position of the charged particle beam on the sample;
a second deflector provided between the charged particle source and the aberration corrector and configured to control a trajectory in the aberration corrector along which the charged particle beam passes; and
a controller configured to control a deflection amount of the second deflector based on the irradiation position controlled by the first deflector.

2. The charged particle beam device according to claim 1, wherein
the first deflector performs scanning of the charged particle beam on the sample, and
the controller controls the deflection amount of the second deflector in conjunction with the scanning of the first deflector.

3. The charged particle beam device according to claim 1, wherein
the first deflector, when moving a scanning region of the charged particle beam on the sample, shifts the irradiation position serving as an origin of the scanning region, and
the controller controls the deflection amount of the second deflector based on a shift amount of the first deflector.

4. The charged particle beam device according to claim 3, wherein
the first deflector further performs scanning of the charged particle beam in the scanning region, and
the controller maintains the deflection amount of the second deflector while the first deflector performs the scanning in the scanning region.

5. The charged particle beam device according to claim 1, wherein
the second deflector is a one-stage deflector, and
the controller controls the deflection amount of the second deflector, with a trajectory along which the charged particle beam travels straight as a central axis, such that the trajectory within the multipole lens along which the charged particle beam passes is translated from the central axis according to the irradiation position controlled by the first deflector.

6. The charged particle beam device according to claim 5, wherein
the controller controls the deflection amount of the second deflector such that the trajectory within the multipole lens is translated to a position away from the central axis as the irradiation position controlled by the first deflector is away from the central axis.

7. The charged particle beam device according to claim 1, wherein
the second deflector is a two-stage deflector, and
the controller controls the deflection amount of the second deflector, with a trajectory along which the charged particle beam travels straight as a central axis, such that an angle formed by the trajectory within the multipole lens along which the charged particle beam passes and the central axis changes according to the irradiation position controlled by the first deflector.

8. The charged particle beam device according to claim 7, wherein
the controller controls the deflection amount of the second deflector such that the angle formed by the trajectory within the multipole lens and the central axis increases as the irradiation position controlled by the first deflector is away from the central axis.

9. The charged particle beam device according to claim 2, further comprising:
a storage device configured to store a first control table representing a relationship between a scanning position of the first deflector and the deflection amount of the second deflector, wherein
the controller
controls the scanning position of the first deflector, and
controls the deflection amount of the second deflector based on the first control table.

10. The charged particle beam device according to claim 3, further comprising:
a storage device configured to store a second control table representing a relationship between the shift amount of the first deflector and the deflection amount of the second deflector, wherein
the controller
controls the shift amount of the first deflector, and
controls the deflection amount of the second deflector based on the second control table.

11. The charged particle beam device according to claim 1, wherein
the controller is configured to select, by setting, whether to enable/disable an operation of controlling the deflection amount of the second deflector.

12. The charged particle beam device according to claim 1, further comprising:
a correction lens provided between the first deflector and the sample stage and configured to correct a high-order aberration.
